(19) United States
(12) Patent Application Publication
(10) Pub. No.: US 2018/0166460 A1
(43) Pub. Date: Jun. 14, 2018

(54) SEMICONDUCTOR DEVICE AND METHOD FOR MANUFACTURING SAME

(71) Applicant: Toshiba Memory Corporation, Minato-ku (JP)

(72) Inventor: Kenzo MANABE, Yokkaichi (JP)

(73) Assignee: Toshiba Memory Corporation, Minato-ku (JP)

(21) Appl. No.: 15/460,741

(22) Filed: Mar. 16, 2017

Related U.S. Application Data
(60) Provisional application No. 62/433,945, filed on Dec. 14, 2016.

(51) Int. Cl. H01L 27/11582; H01L 27/11556; H01L 27/11565; H01L 27/11519; H01L 23/528; H01L 29/45; H01L 29/788; H01L 29/423; H01L 29/51; H01L 21/28

(52) U.S. Cl. CPC H01L 27/11582; H01L 27/11556; H01L 27/11565; H01L 27/11519; H01L 23/5283; H01L 21/28273; H01L 29/7883; H01L 29/42324; H01L 29/4234; H01L 29/517; H01L 21/28282; H01L 29/45

(57) ABSTRACT

A semiconductor device includes a stacked body, a columnar portion and a barrier film. The stacked body includes a plurality of insulating layers and a plurality of electrode layers including aluminum stacked alternately along a first direction. The columnar portion is provided inside the stacked body and extends in the first direction. The columnar portion includes a semiconductor body, a tunneling insulating film, a blocking insulating film and a charge storage portion. The semiconductor body extends in the first direction. The tunneling insulating film is provided between the semiconductor body and the stacked body. The blocking insulating film is provided between the tunneling insulating film and the stacked body. The charge storage portion is provided between the tunneling insulating film and the blocking insulating film. The barrier film includes a metal silicide, and is provided between the blocking insulating film and one of the plurality of electrode layers.

### CROSS-REFERENCE TO RELATED APPLICATIONS

This application is based upon and claims the benefit of priority from U.S. Provisional Patent Application 62/433,945, filed on Dec. 14, 2016; the entire contents of which are incorporated herein by reference.

### FIELD

Embodiments described herein relate generally to a semiconductor device and a method for manufacturing the same.

### BACKGROUND

A semiconductor memory device that has a three-dimensional structure has been proposed in which a memory hole is formed in a stacked body in which multiple electrode layers are stacked, and a charge storage film and a semiconductor film are provided to extend in the stacking direction of the stacked body inside the memory hole. In the semiconductor memory device, multiple memory cells are connected in series between a drain-side selection transistor and a source-side selection transistor. The electrode layers of the stacked body are used as word lines of memory cells and selection gates of the selection transistors. To increase the capacity of the semiconductor memory device, it is desirable to reduce the film thickness of the stacked body. To reduce the film thickness of the stacked body while ensuring the operation speed of the circuit, it is desirable to reduce the resistance of the electrode layers.

### BRIEF DESCRIPTION OF THE DRAWINGS

FIG. 1 is a plan view showing a planar layout of a semiconductor device according to an embodiment;

FIG. 2 is a perspective view of a memory cell array of the semiconductor device according to the embodiment;

FIG. 3A and FIG. 3B are cross-sectional views showing the semiconductor device according to the embodiment;

FIG. 4 and FIG. 5 are enlarged cross-sectional views illustrating a columnar portion and a periphery of the columnar portion of the semiconductor device according to the embodiment;

FIG. 6 is a schematic view showing energy band of memory films in an erase operation of a semiconductor device according to a reference example;

FIG. 7 is a schematic view showing energy band of memory films in an erase operation of the semiconductor device according to the embodiment;

FIG. 8A to FIG. 17B are schematic cross-sectional views showing a method for manufacturing the semiconductor device according to the embodiment;

FIG. 18 is a schematic cross-sectional view showing the method for manufacturing the semiconductor device according to the embodiment; and

FIG. 19A to FIG. 23B are schematic cross-sectional views showing the method for manufacturing the semiconductor device according to the embodiment.

### DETAILED DESCRIPTION

A semiconductor device includes a stacked body, a columnar portion and a barrier film. The stacked body includes a plurality of insulating layers and a plurality of electrode layers stacked alternately along a first direction. The plurality of electrode layers includes aluminum. The columnar portion is provided inside the stacked body. The columnar portion extends in the first direction. The columnar portion includes a semiconductor body, a tunneling insulating film, a blocking insulating film and a charge storage portion. The semiconductor body extends in the first direction. The tunneling insulating film is provided between the semiconductor body and the stacked body. The blocking insulating film is provided between the tunneling insulating film and the stacked body. The charge storage portion is provided between the tunneling insulating film and the blocking insulating film. The barrier film is provided between the blocking insulating film and one of the plurality of electrode layers. The barrier film includes a metal silicide.

Hereinafter, embodiments will be described with reference to the drawings. In each drawing, the same reference numerals are attached to the same elements. The semiconductor device of the embodiment is a semiconductor memory device having a memory cell array.

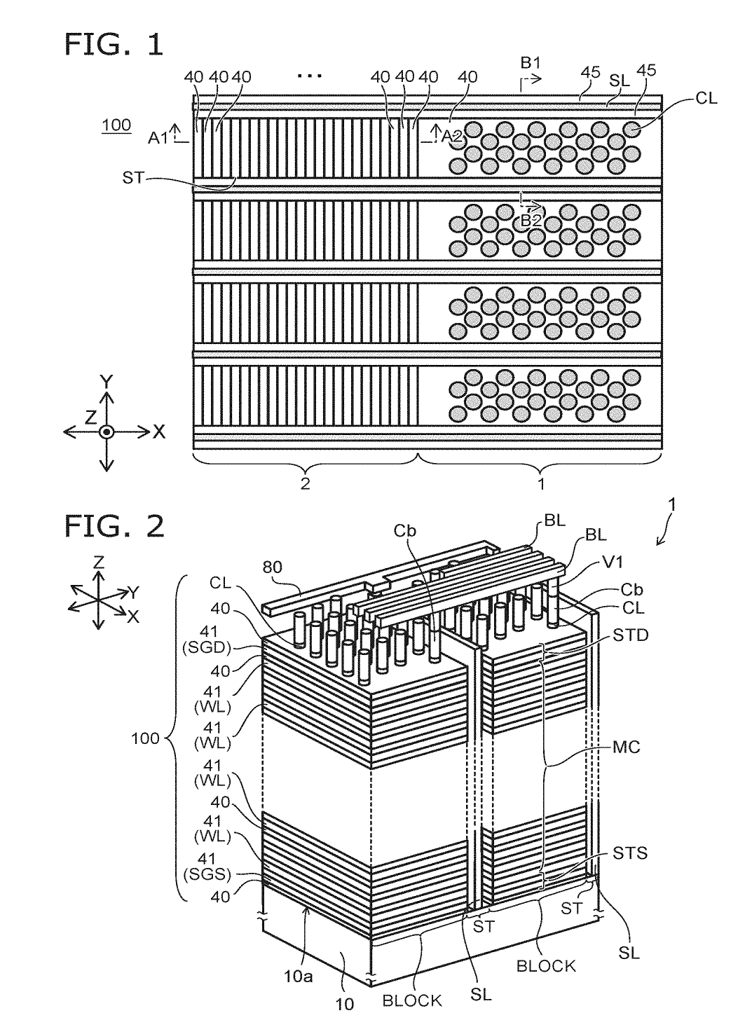

FIG. 1 is a plan view showing a planar layout of the semiconductor device according to the embodiment.

FIG. 2 is a perspective view of a memory cell array of the semiconductor device according to the embodiment.

As shown in FIG. 1 and FIG. 2, the semiconductor device according to the embodiment includes a substrate 10 and a stacked body 100. For example, the stacked body 100 is provided on a major surface 10a of the substrate 10. In FIG. 1 and FIG. 2, two mutually-orthogonal directions parallel to the major surface 10a of the substrate 10 are taken as an X-direction and a Y-direction. A direction crossing, e.g., orthogonal to, both the X-direction and the Y-direction is taken as a Z-direction. In the specification, “down” refers to the direction from the stacked body 100 toward the substrate 10; and “up” refers to the direction from the substrate 10 toward the stacked body 100.

The stacked body 100 includes a memory cell array 1 and a staircase portion 2. The staircase portion 2 is provided on the outer side of the memory cell array 1. Columnar portions CL are provided in the memory cell array 1. The configuration of the staircase portion 2 is a staircase configuration.

The stacked body 100 is divided by a slit ST spreading along the Z-direction and the X-direction. A source line SL that spreads along the Z-direction and the X-direction is provided inside the slit ST. The lower end of the slit ST reaches the substrate 10. An insulating portion 45 is provided between the source line SL and the stacked body 100. The source line SL is disposed inside the slit ST in a state of being electrically insulated from electrode layers 41 of the stacked body 100. For example, the lower end of the source line SL is electrically connected to the substrate 10. The upper end of the source line SL is connected to a shunt interconnect 80. The shunt interconnect 80 electrically provides a shunt connection of the multiple source lines SL along the Y-direction.

The substrate 10 includes, for example, a crystallized p-type silicon layer. The stacked body 100 includes multiple insulating layers 40 and the multiple electrode layers 41 stacked alternately. The insulating layer 40 includes an insulator. The insulator is, for example, silicon oxide. The electrode layer 41 includes aluminum and is made of, for example, aluminum.

The multiple electrode layers 41 include at least one source-side selection gate (SGS), multiple word lines WL, and at least one drain-side selection gate (SGD). The source-side selection gate (SGS) is a gate electrode of a source-side selection transistor STS. The word lines (WL) are gate electrodes of memory cells MC. The drain-side selection gate (SGD) is a gate electrode of a drain-side selection transistor STD. The number of stacks of the electrode layers 41 is arbitrary.

The source-side selection gate (SGS) is provided in the lower region of the stacked body 100. The drain-side selection gate (SGD) is provided in the upper region of the stacked body 100. The lower region refers to the region of the stacked body 100 on the side proximal to the substrate 10; and the upper region refers to the region of the stacked body 100 on the side distal to the substrate 10. For example, at least one of the multiple electrode layers 41 including the electrode layer 41 most proximal to the substrate 10 is used as the source-side selection gate (SGS). At least one of the multiple electrode layers 41 including the electrode layer 41 most distal to the substrate 10 is used as the drain-side selection gate (SGD). The word lines WL are provided in an intermediate region of the stacked body 100 between the lower region and the upper region.

The columnar portions CL are provided inside the stacked body 100. The columnar portions CL extend in the Z-direction, i.e., the stacking direction of the stacked body 100. For example, the upper end of the columnar portion CL is electrically connected to a bit line BL via a contact Cb and a conductive body V1. For example, the bit line BL extends in the Y-direction crossing the slit ST.

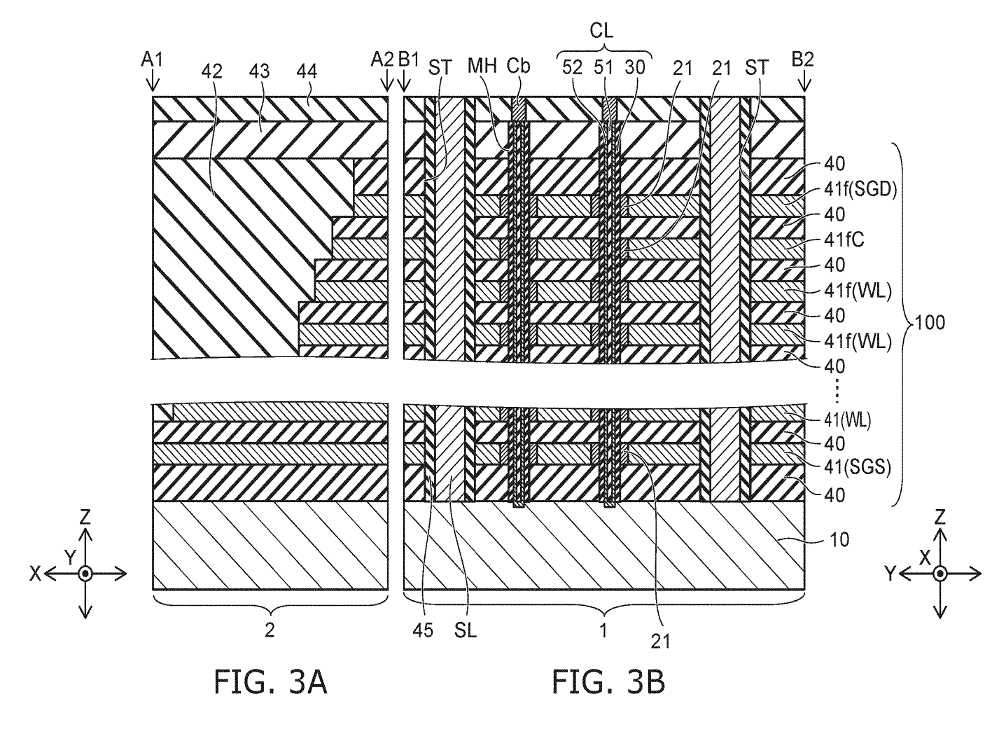

FIG. 3A and FIG. 3B are cross-sectional views showing the semiconductor device according to the embodiment.

FIG. 3A is a cross-sectional view showing a cross section along line A1-A2 shown in FIG. 1; and FIG. 3B is a cross-sectional view showing a cross section along line B1-B2 shown in FIG. 1.

In the memory cell array 1 as shown in FIG. 3B, a memory hole MH is formed inside the stacked body 100. The memory hole MH is an opening extending in the Z-direction. The columnar portion CL is provided inside the memory hole MH. The memory hole MH is formed in a circular columnar configuration or an elliptical columnar configuration. For example, the lower end of the memory hole MH reaches the substrate 10.

The columnar portion CL includes a core portion 51, a semiconductor body 52, and a memory film 30. The core portion 51 extends through the stacked body 100 in the Z-direction. The semiconductor body 52 is provided between the core portion 51 and the stacked body 100. For example, the semiconductor body 52 has a cylindrical configuration in which the lower end is plugged. The memory film 30 is provided between the semiconductor body 52 and the stacked body 100. For example, the memory film 30 has a cylindrical configuration.

In the staircase portion 2 as shown in FIG. 3A, an insulating film 42 is provided on the portion of the stacked body 100 having the staircase configuration. For example, the position in the Z-direction of the upper surface of the insulating film 42 and the position in the Z-direction of the upper surface of the stacked body 100 are substantially equal. An insulating film 43 is provided on the stacked body 100 and the insulating film 42. An insulating film 44 is provided on the insulating film 43. For example, the columnar portion CL extends through the insulating film 43 and the stacked body 100 in the Z-direction. The contact Cb is provided inside the insulating film 44.

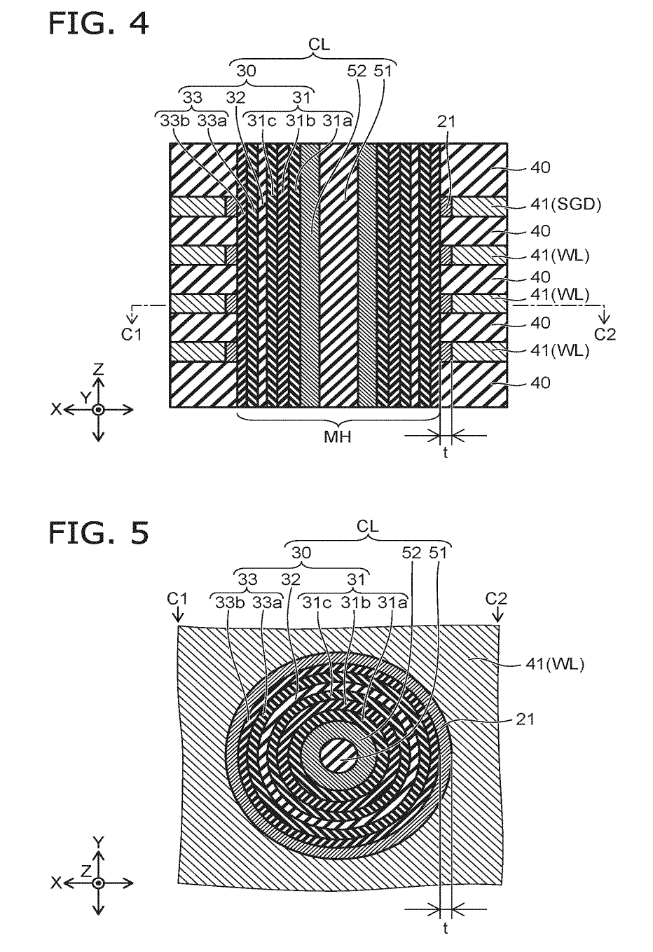

FIG. 4 and FIG. 5 are enlarged cross-sectional views illustrating the columnar portion and the periphery of the columnar portion of the semiconductor device according to the embodiment. FIG. 5 is an enlarged cross-sectional view illustrating a cross section along line C1-C2 shown in FIG. 4.

As shown in FIG. 4 and FIG. 5, for example, the core portion 51 has a circular columnar configuration. The core portion 51 includes, for example, silicon oxide. The semiconductor body 52 extends in the Z-direction. The semiconductor body 52 includes, for example, p-type silicon that is crystallized. The memory film 30 includes a tunneling insulating film 31, a charge storage portion 32, and a blocking insulating film 33. The memory film 30 includes the tunneling insulating film 31 between the charge storage portion 32 and the semiconductor body 52. The memory film 30 includes the blocking insulating film 33 between the charge storage portion 32 and the electrode layers 41.

Tunneling of charge, e.g., electrons, occurs in the tunneling insulating film 31 when erasing the information and when programming the information.

For example, the tunneling insulating film 31 includes a first tunneling film 31a, a second tunneling film 31b, and a third tunneling film 31c. The first tunneling film 31a is provided between the semiconductor body 52 and the charge storage portion 32. The second tunneling film 31b is provided between the first tunneling film 31a and the charge storage portion 32. The third tunneling film 31c is provided between the second tunneling film 31b and the charge storage portion 32. The first tunneling film 31a includes, for example, silicon oxide. The second tunneling film 31b includes, for example, silicon nitride. The third tunneling film 31c includes, for example, silicon oxide.

The charge storage portion 32 includes, for example, trap sites that trap charge and/or a floating gate. The threshold voltage of the memory cell MC changes depending on the existence or absence of the charge or the amount of the charge inside the charge storage portion 32. Thereby, the memory cell MC stores information.

For example, the blocking insulating film 33 includes a first blocking film 33a and a second blocking film 33b. The first blocking film 33a is provided between the charge storage portion 32 and the stacked body 100. The second blocking film 33b is provided between the first blocking film 33a and the stacked body 100. The first blocking film 33a includes, for example, silicon oxide. The second blocking film 33b may include, for example, an oxide of a first element. In such a case, the first element includes, for example, at least one of zirconium, aluminum, and hafnium.

For example, the blocking insulating film 33 may be provided in one layer. For example, the blocking insulating film 33 may include an oxide of the first element. In such a case, the first element is, for example, at least one of silicon, zirconium, aluminum, and hafnium.

A barrier film 21 is provided between the blocking insulating film 33 and the electrode layers 41. The barrier film 21 includes a metal silicide. In the case where the blocking insulating film 33 includes the first blocking film 33a and the second blocking film 33b, for example, the barrier film 21 is provided between the second blocking film 33b and the electrode layers 41.

For example, the free energy of oxide formation of the metal included in the metal silicide is higher than the free energy of oxide formation of the first element described above (the element selected from the group consisting of silicon, zirconium, aluminum, and hafnium). Therefore, the metal that is included in the metal silicide is oxidized less easily than the first element included in the blocking insulating film 33; and the oxide of the first element included in the blocking insulating film 33 is not reduced by the oxidizing of the metal included in the metal silicide.

The metal silicide that is included in the barrier film 21 includes, for example, at least one of tungsten, cobalt, and nickel.

A thickness t of the barrier film 21 between the blocking insulating film 33 and the electrode layers 41 is, for example, not less than 5 nm and not more than 20 nm, and more favorably not less than 5 nm and not more than 10 nm. For example, the work function of the barrier film 21 is higher than the work function of aluminum.

For example, the electrode layer 41 and the barrier film 21 contact each other. For example, the barrier film 21 and the blocking insulating film 33 contact each other.

The memory film 30 may be removed at the portion where the electrode layer 41 used as the drain-side selection gate SGD is formed. In such a case, the gate insulating film of the drain-side selection transistor STD is formed instead of the memory film 30.

As shown in FIG. 5, the columnar portion CL has a substantially circular columnar configuration. The barrier film is provided to surround the periphery of the columnar portion CL. For example, the barrier film 21 is a circular tube having a central axis extending in the Z-direction. As shown in FIG. 4, for example, the barrier film 21 is not provided between the electrode layer 41 and the insulating layer 40.

When the information is programmed to the memory cell MC, the potential of the electrode layer 41 is set to be high with respect to the potential of the semiconductor body 52 (the program operation). Thereby, electrons are injected from the semiconductor body 52 into the charge storage portion 32. In the case where the information is erased from the memory cell MC, the potential of the electrode layer 41 is set to be low with respect to the potential of the semiconductor body 52 (the erase operation). Thereby, holes are injected from the semiconductor body 52 into the charge storage portion 32.

Effects of the embodiment will now be described.

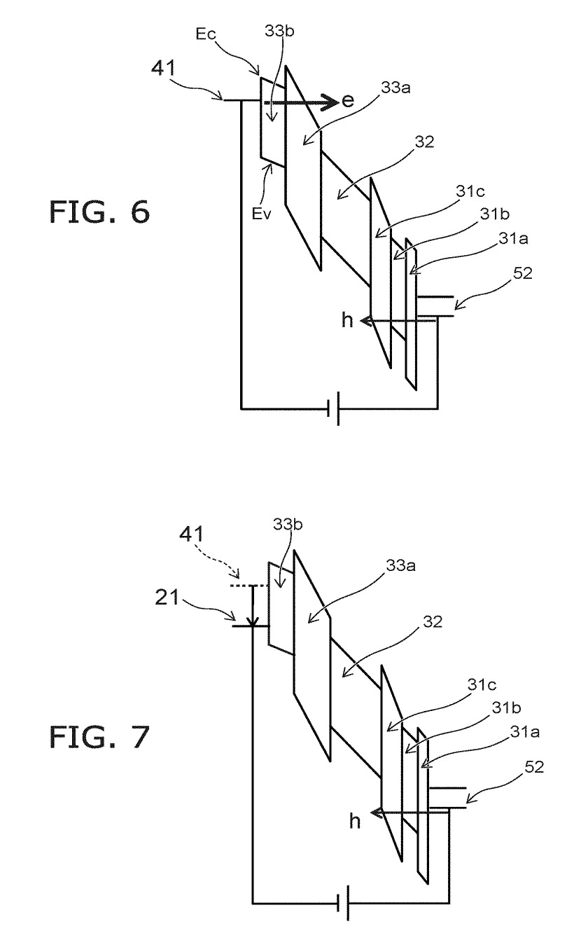

FIG. 6 is a schematic view showing the energy band of the memory films in the erase operation of a semiconductor device according to a reference example.

FIG. 7 is a schematic view showing the energy band of the memory films in the erase operation of the semiconductor device according to the embodiment.

FIG. 6 is a schematic view showing the energy bands of a semiconductor device in which the barrier film 21 is not provided. In the drawing, Ec illustrates the conduction band edge. Ev illustrates the valence band edge.

In the reference example, the electrode layer 41 that includes aluminum contacts the blocking insulating film 33 as shown in FIG. 6. By the erase operation, holes h move from the semiconductor body 52 into the charge storage portion 32. At this time, back-tunneling may occur because the work function of the aluminum included in the electrode layer 41 is low (about 4 eV). In other words, in the erase operation, electrons are injected into the charge storage portion 32 from the electrode layer 41; and the erase characteristics of the semiconductor device degrade.

In the embodiment, the barrier film 21 is provided between the electrode layer 41 and the blocking insulating film 33. As shown in FIG. 7, the effective work function of the barrier film 21 is higher than the work function of aluminum. For example, in the case where the barrier film 21 includes a silicide of tungsten, the work function of the barrier film 21 is about the silicon midgap (about 4.6 eV). Thereby, the back-tunneling is suppressed. In the case where the thickness t of the barrier film 21 between the blocking insulating film 33 and the electrode layer 41 is thinner than 5 nm, there are cases where effects arise due to the work function of the electrode layer 41. Accordingly, it is favorable for the thickness t of the barrier film 21 to be 5 nm or more.

In the case of the reference example, the electrode layer 41 that includes aluminum contacts the blocking insulating film 33. Therefore, the aluminum of the electrode layer 41 diffuses into the blocking insulating film 33 and reduces the oxide of the first element included in the blocking insulating film 33. Thereby, the insulative properties of the blocking insulating film 33 degrade.

In the case of the embodiment, the barrier film 21 is provided between the blocking insulating film 33 and the electrode layer 41 including aluminum. Thereby, the blocking insulating film 33 and the electrode layer 41 are not in direct contact. For example, the degradation of the insulative properties of the blocking insulating film 33 caused by the aluminum which has a strong reducibility is suppressed. Further, the diffusion into the blocking insulating film 33 of the aluminum included in the electrode layer 41 is suppressed.

A configuration may be considered in which the electrode layer 41 is made of tungsten. However, the electrical resistivity of tungsten (about 53 nΩm) is high compared to the electrical resistivity of aluminum (about 28 nΩm). Accordingly, in the case of such a configuration, the electrode layer 41 that is made of tungsten must be set to be thick to ensure the operation speed of the circuit. Thereby, the increased capacity of the semiconductor memory device is obstructed.

In the case of the embodiment, the electrode layer 41 includes aluminum. Thereby, the electrode layer 41 has lower resistance compared to the case where tungsten is included. Accordingly, the film thickness that is desired for the electrode layer 41 to ensure the operation speed of the circuit can be thin compared to the case of the electrode layer 41 made of tungsten. Accordingly, even more layers of the stacked body 100 are possible.

A configuration may be considered in which the barrier film 21 is provided between the blocking insulating film 33 and the electrode layer 41 and between the insulating layer 40 and the electrode layer 41. However, in such a case, the barrier film undesirably occupies a portion of the stacked body 100 in the Z-direction.

In the case of the embodiment, the barrier film 21 is provided as a tube around the blocking insulating film 33 and does not exist between the insulating layer 40 and the electrode layer 41. Thereby, the thickness of the electrode layer 41 in the Z-direction can be ensured; and sufficient conductivity of the electrode layer 41 can be maintained. Even in the case where the barrier film 21 does not exist between the insulating layer 40 and the electrode layer 41, if the thickness t of the barrier film 21 is thick in a direction orthogonal to the Z-direction, the volume ratio in the electrode layer 41 occupied by aluminum which has a low resistance decreases; and there is a risk of a conductivity decrease of the electrode layer 41. Accordingly, it is favorable for the thickness t of the barrier film 21 to be 20 nm or less, and more favorable to be 10 nm or less.

A method for manufacturing the semiconductor device according to the embodiment will now be described.

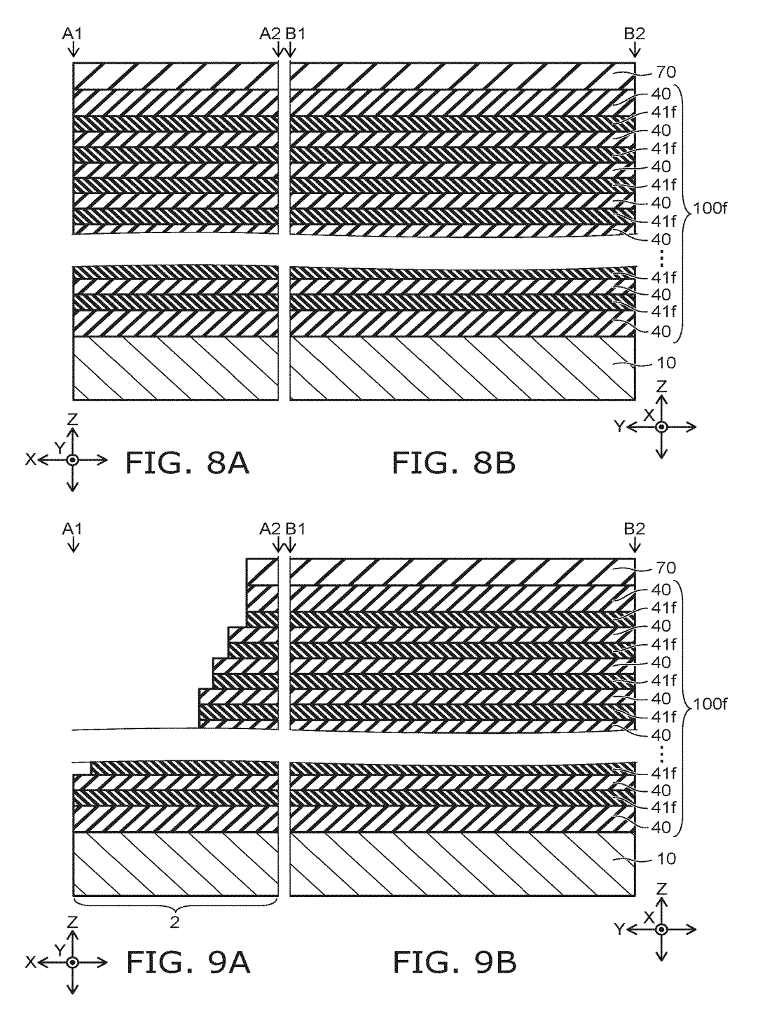

FIG. 8A to FIG. 17B are schematic cross-sectional views showing the method for manufacturing the semiconductor device according to the embodiment.

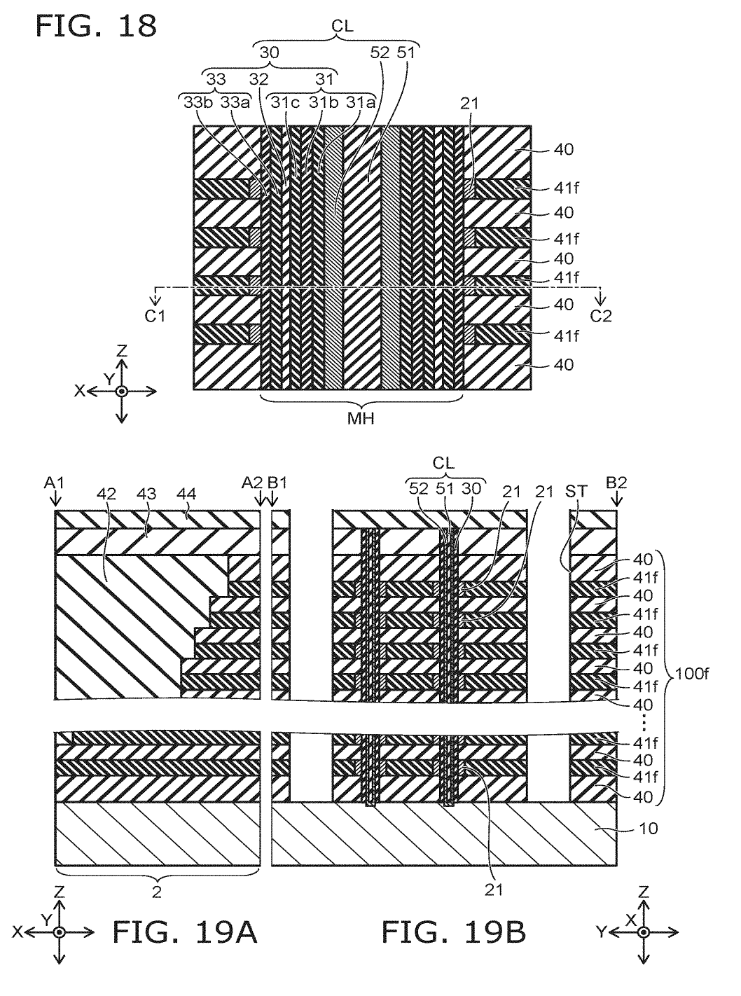

FIG. 18 is a schematic cross-sectional view showing the method for manufacturing the semiconductor device according to the embodiment.

FIG. 19A to FIG. 23B are schematic cross-sectional views showing the method for manufacturing the semiconductor device according to the embodiment.

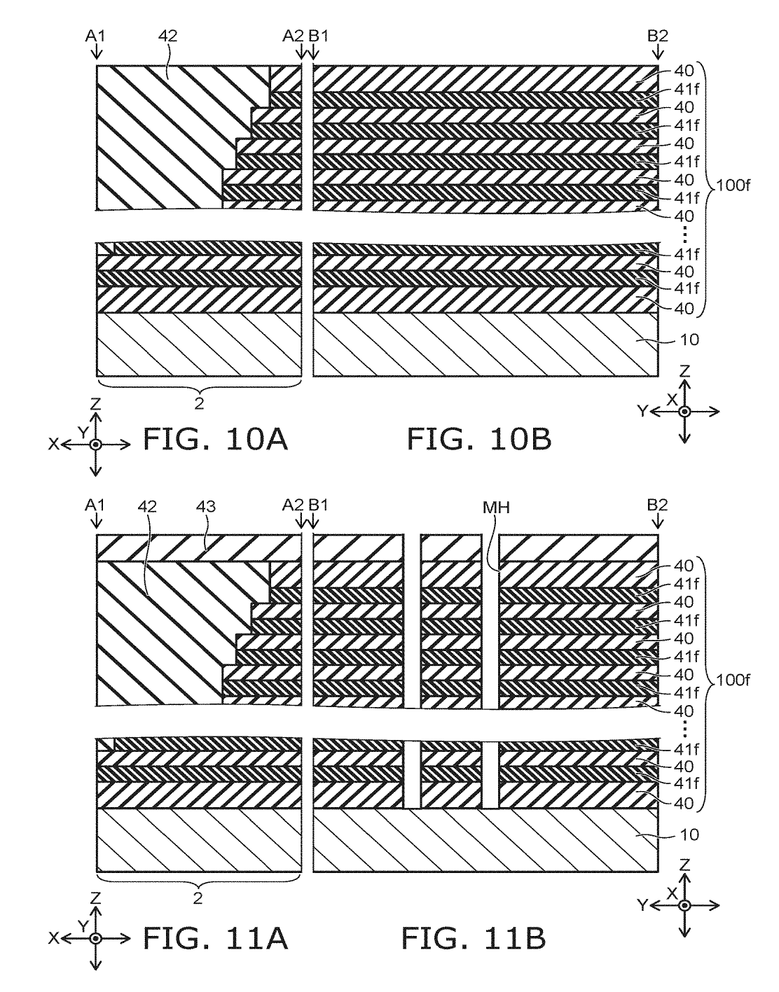

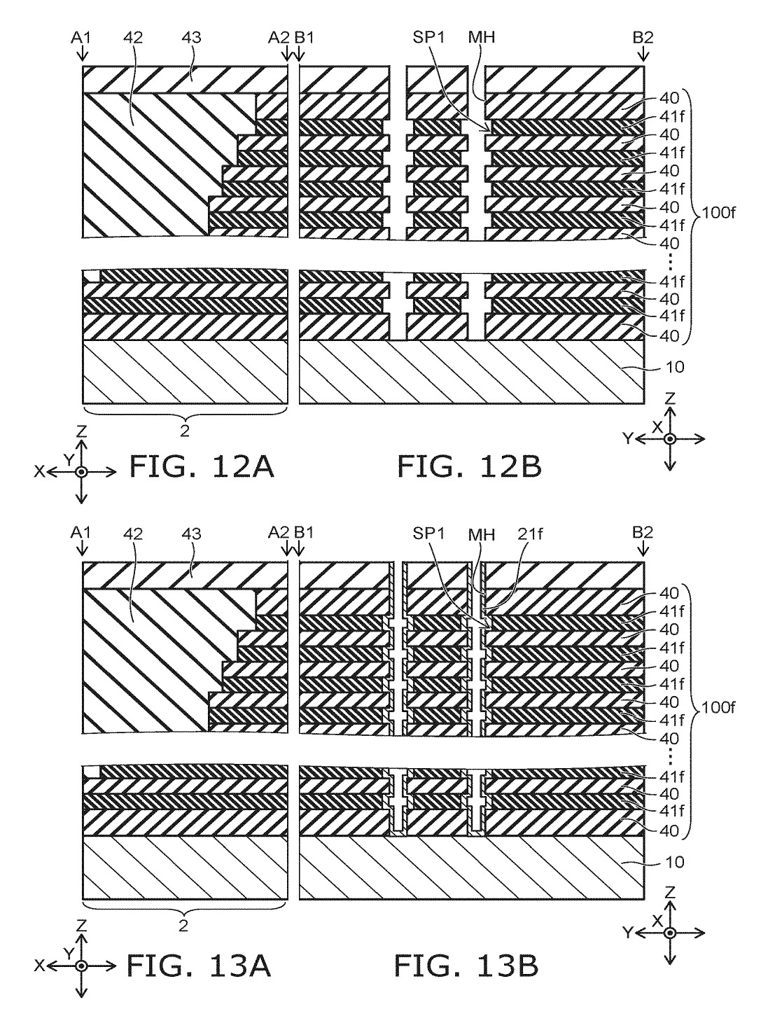

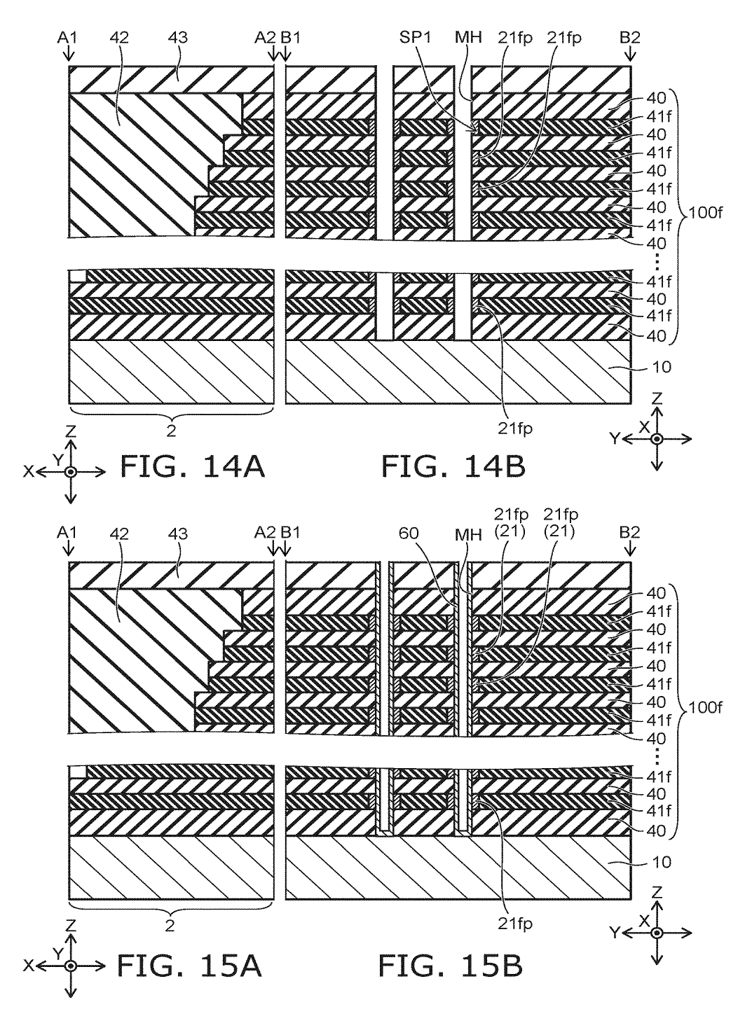

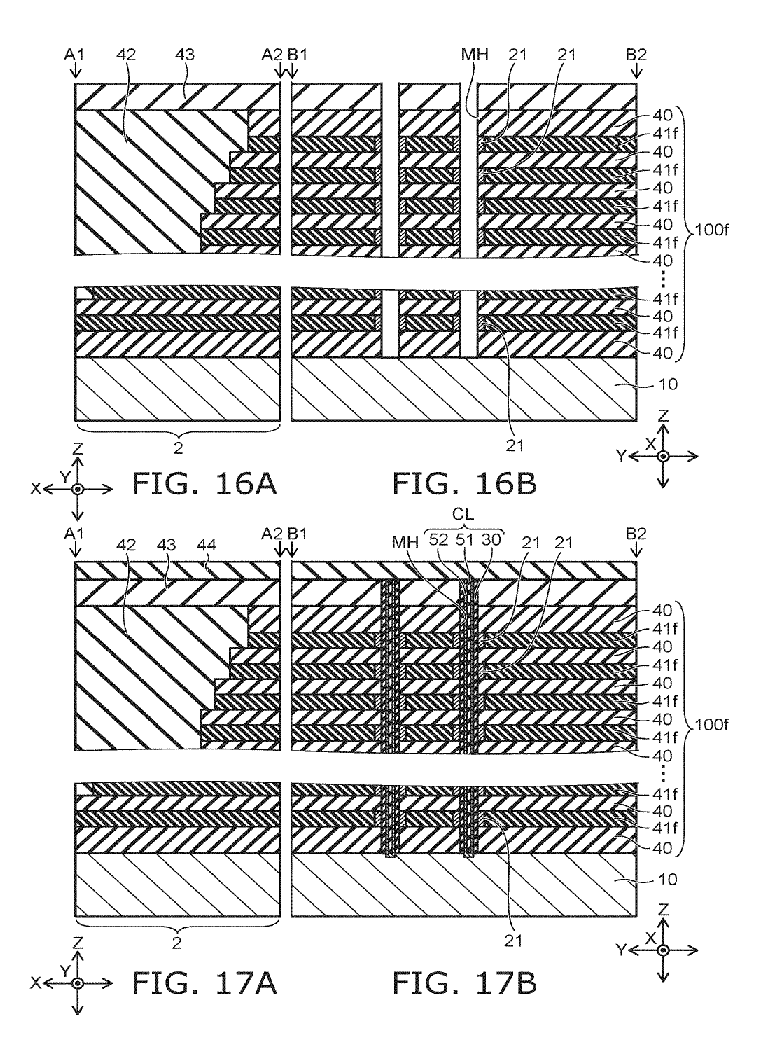

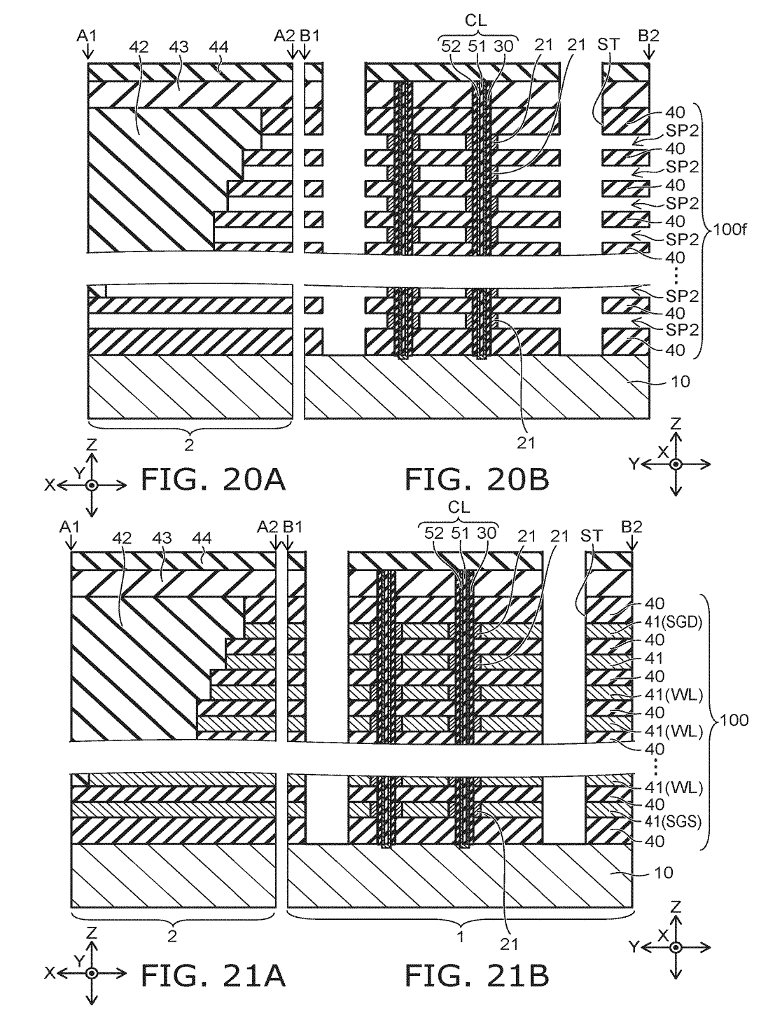

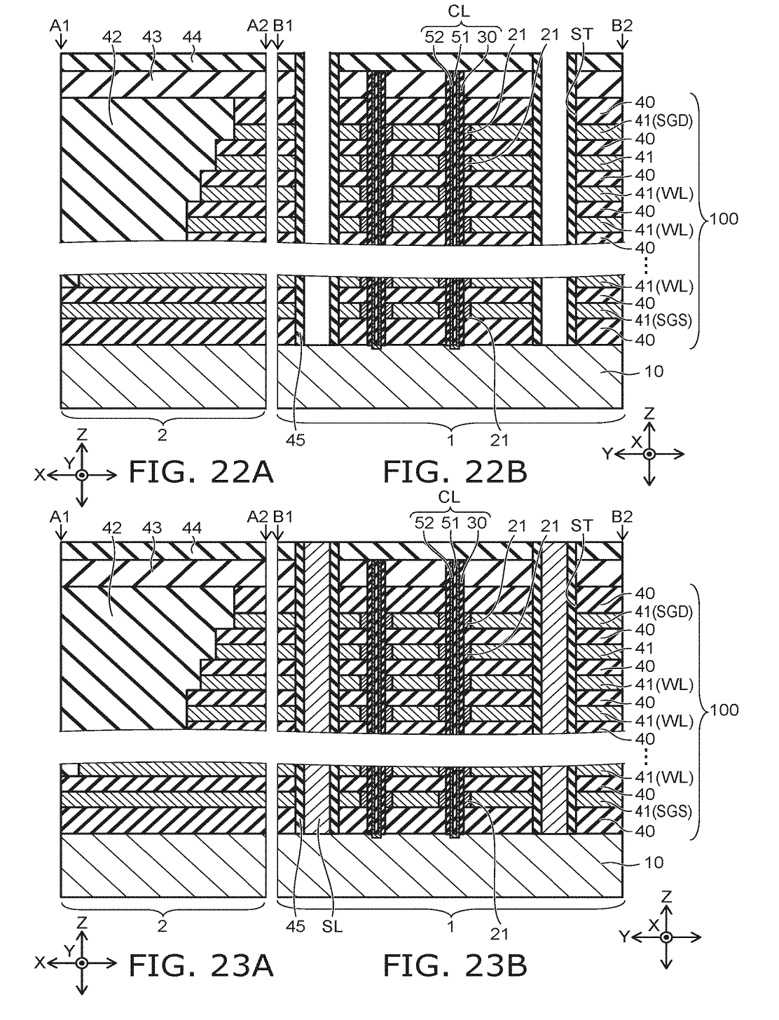

FIG. 8A, FIG. 9A, FIG. 10A, FIG. 11A, FIG. 12A, FIG. 13A, FIG. 14A, FIG. 15A, FIG. 16A, FIG. 17A, FIG. 19A, FIG. 20A, FIG. 21A, FIG. 22A, and FIG. 23A correspond to the cross section along line A1-A2 shown in FIG. 1. FIG. 8B, FIG. 9B, FIG. 10B, FIG. 11B, FIG. 12B, FIG. 13B, FIG. 14B, FIG. 15B, FIG. 16B, FIG. 17B, FIG. 19B, FIG. 20B, FIG. 21B, FIG. 22B, and FIG. 23B correspond to the cross section along line B1-B2 shown in FIG. 1. FIG. 18 is an enlarged cross-sectional view illustrating the columnar portion and the periphery of the columnar portion shown in FIG. 17B.

First, as shown in FIG. 8A and FIG. 8B, the multiple insulating layers 40 and multiple replacement members 41f (first layers) are stacked alternately on the substrate 10. Thereby, a stacked body 100f that includes the multiple replacement members 41f stacked with the insulating layers 40 interposed is formed. The replacement members 41f are layers that are replaced with the electrode layers 41 (SGD, WL, and SGS) subsequently. The material of the replacement members 41f is selected from materials that can provide etching selectivity with respect to the insulating layers 40. For example, in the case where silicon oxide is selected as the insulating layers 40, silicon nitride is selected as the material of the replacement members 41f. A stopper film 70 may be formed on the stacked body 100f.

Then, as shown in FIG. 9A and FIG. 9B, the end portion of the stacked body 100f is patterned into a staircase configuration. Thereby, the staircase portion 2 is formed. It is sufficient for the formation of the staircase portion 2 to be performed using a well-known method such as resist slimming, etc. For example, at the end portion of the stacked body 100f, anisotropic etching and slimming of the resist are repeated. At this time, for example, a pair of the insulating layer 40 and the replacement member 41f is caused to recede one pair at a time from the end portion of the stacked body 100f toward the inner side. Thereby, the end portion of the stacked body 100f is patterned into the staircase configuration. For example, the staircase portion 2 has a staircase configuration in which a step is formed every pair of the insulating layer 40 and the replacement member 41f. For example, the insulating layer 40 is disposed on the front surface side of each terrace of the staircase portion 2. In the case where the stopper film 70 is provided on the stacked body 100f, the stopper film 70 also is patterned with the stacked body 100f.

Then, as shown in FIG. 10A and FIG. 10B, the insulating film 42 is formed on the portion of the stacked body 100f patterned into the staircase configuration. Subsequently, planarization is performed by CMP (chemical mechanical polishing). At this time, the stopper film 70 functions as a stopper of the CMP. The positions in the Z-direction of the upper surface of the insulating film 42 and the upper surface of the stacked body 100f are substantially equal. The stopper film 70 is removed in the CMP process.

Then, as shown in FIG. 11A and FIG. 11B, the insulating film 43 is formed on the stacked body 100f and on the insulating film 42. Then, the memory holes MH that extend through the insulating film 43 and the stacked body 100f in the Z-direction are formed. The bottoms of the memory holes MH reach the substrate 10. For example, the memory holes MH are formed using anisotropic etching such as RIE (Reactive Ion Etching), etc.

Then, as shown in FIG. 12A and FIG. 12B, the end surfaces of the multiple replacement members 41f exposed at the side surfaces of the memory holes MH are caused to recede. For example, the replacement members 41f are etched via the memory holes MH. For example, in the case where the replacement members 41f include silicon nitride, the replacement members 41f are etched using an etchant including phosphoric acid. Thereby, the end surfaces of the replacement members 41f recede. For example, the replacement members 41f are caused to recede not less than 5 nm and not more than 20 nm from the side surfaces of the memory holes MH. More favorably, the replacement members 41f are caused to recede not less than 5 nm and not more than 10 nm from the side surfaces of the memory holes MH. By the replacement members 41f receding, first spaces SP1 occur respectively between the multiple replacement members 41f and the memory holes MH.

Then, as shown in FIG. 13A and FIG. 13B, a semiconductor layer 21f is formed on the inner surfaces of the memory holes MH and inside the first spaces SP1. The semiconductor layer 21f is formed of a material including, for example, silicon.

Then, as shown in FIG. 14A and FIG. 14B, the semiconductor layer 21f that is formed on the inner surfaces of the memory holes MH is removed. For example, the semiconductor layer 21f that is formed on the inner surfaces of the memory holes MH is removed by anisotropic etching such as RIE, etc. At this time, the semiconductor layer 21f remains in each of the multiple first spaces SP1. The semiconductor layer 21f that remains becomes multiple semiconductor layers 21fp.

Then, as shown in FIG. 15A and FIG. 15B, a metal layer 60 is formed on the inner surfaces of the memory holes MH. Thereby, the metal layer 60 is formed on the side surfaces of the semiconductor layers 21fp. For example, the metal layer 60 is formed using CVD (Chemical Vapor deposition). The metal layer 60 is formed of a material that includes a metal having a free energy of oxide formation that is higher than the free energy of oxide formation of the first element. For example, the first element includes at least one of silicon, zirconium, aluminum, and hafnium. For example, the metal layer 60 is formed of a material including at least one of tungsten, cobalt, and nickel.

Subsequently, annealing is performed. Thereby, the semiconductor layers 21fp are silicided by reacting with the metal layer 60. The semiconductor layers 21fp that are silicided become the barrier films 21. Then, as shown in FIG. 16A and FIG. 16B, the unreacted metal layer 60 is removed by introducing a mixed liquid of sulfuric acid and aqueous hydrogen peroxide (SPM) to the memory holes MH.

A portion of the substrate 10 may be silicided by the substrate 10 reacting with the metal layer 60. Thereby, the barrier film may be formed on the bottoms of the memory holes MH as well. In such a case, the barrier film that is formed on the bottoms of the memory holes MH is removed by, for example, anisotropic etching such as RIE, etc.

Then, as shown in FIG. 17A and FIG. 17B, the columnar portions CL are formed inside the memory holes MH.

For example, as shown in FIG. 18, the blocking insulating film 33, the charge storage portion 32, and the tunneling insulating film 31 are formed in this order on the inner surfaces of the memory hole MH. Thereby, the memory film 30 is formed.

For example, the second blocking film 33b is formed on the inner surface of the memory hole MH; and the first blocking film 33a is formed on the second blocking film 33b. Thereby, the blocking insulating film 33 is formed. In such a case, the first blocking film 33a is formed using a material including, for example, silicon oxide. For example, the second blocking film 33b is formed using a material including an oxide of the first element. In such a case, the first element includes, for example, at least one of zirconium, aluminum, and hafnium.

The blocking insulating film 33 may be formed in one layer. For example, the blocking insulating film 33 may include an oxide of the first element. In such a case, the first element is, for example, at least one of silicon, zirconium, aluminum, and hafnium.

For example, the charge storage portion 32 is formed by depositing silicon nitride on the blocking insulating film 33.

The third tunneling film 31c, the second tunneling film 31b, and the first tunneling film 31a are formed in this order on the charge storage portion 32. Thereby, the tunneling insulating film 31 is formed. For example, the first tunneling film 31a is formed using a material including silicon oxide. For example, the second tunneling film 31b is formed using a material including silicon nitride. For example, the third tunneling film 31c is formed using a material including silicon oxide. Thus, the memory film 30 is formed.

Then, a cover silicon layer (not illustrated) is formed on the memory film 30. Then, the cover silicon layer and the memory film 30 that are on the bottom surface of the memory hole MH are removed by performing RIE. Then, body silicon is formed on the cover silicon layer. Thereby, the semiconductor body 52 is formed. Subsequently, for example, the core portion 51 is formed by depositing silicon oxide in the space surrounded with the semiconductor body 52 having the cylindrical configuration. Thereby, the columnar portion CL is formed.

Then, as shown in FIG. 19A and FIG. 19B, the slits ST that spread through the stacked body 100f along the X-direction and the Z-direction are formed. The slits ST reach the substrate 10.

Then, the replacement members 41f are removed as shown in FIG. 20A and FIG. 20B. For example, the replacement members 41f are etched via the slit ST. For example, in the case where the insulating layers 40 include silicon oxide and the replacement members 41f include silicon nitride, the replacement members 41f are etched by introducing hot phosphoric acid to the slit ST. Thereby, the replacement members 41f are removed. Second spaces SP2 occur by removing the replacement members 41f.

Then, as shown in FIG. 21A and FIG. 21B, a conductive material that includes aluminum is deposited inside the second spaces SP2 via the slit ST. For example, the conductive material that includes aluminum is deposited using CVD. Then, by performing etching, the conductive material that is deposited inside the slit ST is removed; and the conductive material is caused to remain only inside the second spaces SP2. Thereby, the conductive material inside the second spaces SP2 becomes the electrode layers 41 (SGD, WL, and SGS); the stacked body 100f becomes the stacked body 100; and the memory cell array 1 is formed. At this time, the electrode layers 41 contact the barrier films 21.

Then, as shown in FIG. 22A and FIG. 22B, an insulating film is formed on the side surfaces of the slits ST. For example, a film that includes silicon nitride is formed on the inner surfaces of the slits ST. Subsequently, the insulating portions 45 are formed by performing etch-back.

Then, as shown in FIG. 23A and FIG. 23B, the source lines SL are formed inside the slits ST. Subsequently, as shown in FIG. 2, the contacts Cb and the conductive bodies V1 are formed on the columnar portions CL; and the bit lines BL and the shunt interconnect 80 are formed on the stacked body 100.

By implementing the processes recited above, the semiconductor device according to the embodiment is manufactured.

In the method for manufacturing the semiconductor device according to the embodiment, the electrode layers 41 are formed of a conductive material including aluminum. By using aluminum which has a low resistivity as the material, a resistance reduction of the electrode layers 41 can be realized. Because the resistivity of the electrode layers 41 is low, the electrode layers 41 can be thinner while ensuring the operation speed of the circuit. Thereby, even more layers of the stacked body 100 are possible. Further, because the height in the Z-direction of the stacked body 100 (100f) can be set to be low, the formation process of the memory holes MH is easy. For example, the yield in the manufacturing process is improved.

According to the embodiments described above, a semiconductor device in which the resistance of the electrode layers is low can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a stacked body including a plurality of insulating layers and a plurality of electrode layers stacked alternately along a first direction, the plurality of electrode layers including aluminum;
a columnar portion extending in the first direction and being provided inside the stacked body, the columnar portion including
a semiconductor body extending in the first direction,
a tunneling insulating film provided between the semiconductor body and the stacked body,
a blocking insulating film provided between the tunneling insulating film and the stacked body, and
a charge storage portion provided between the tunneling insulating film and the blocking insulating film; and
a barrier film including a metal silicide and being provided between the blocking insulating film and one of the plurality of electrode layers.

2. The device according to claim 1, wherein a thickness of the barrier film between the blocking insulating film and the electrode layer is not less than 5 nm and not more than 20 nm.

3. The device according to claim 1, wherein a work function of the barrier film is higher than a work function of aluminum.

4. The device according to claim 1, wherein the electrode layer contacts the barrier film.

5. The device according to claim 1, wherein the barrier film contacts the blocking insulating film.

6. The device according to claim 1, wherein the blocking insulating film includes one or more oxides selected from the group consisting of silicon oxide, zirconium oxide, aluminum oxide, and hafnium oxide.

7. The device according to claim 1, wherein
the blocking insulating film includes an oxide of a first element, and
a free energy of oxide formation of a metal included in the metal silicide is higher than a free energy of oxide formation of the first element.

8. The device according to claim 7, wherein the first element is one or more elements selected from the group consisting of silicon, zirconium, aluminum, and hafnium.

9. The device according to claim 1, wherein the metal silicide includes one or more metals selected from the group consisting of tungsten, cobalt, and nickel.

10. The device according to claim 1, wherein a configuration of the barrier film is tubular.

11. The device according to claim 1, wherein
the blocking insulating film includes:
a first blocking film provided between the charge storage portion and the stacked body; and
a second blocking film provided between the first blocking film and the stacked body.

12. A method for manufacturing a semiconductor device, comprising:
forming a stacked body including a plurality of insulating layers and a plurality of first layers stacked alternately along a first direction;
forming a hole extending in the first direction inside the stacked body;
causing the plurality of first layers exposed at a side surface of the hole to recede;
forming a layer inside a first space occurring where the plurality of first layers receded, the layer including silicon;
siliciding the layer including silicon;
forming a blocking insulating film on a side surface of the hole;
forming a charge storage portion on a side surface of the blocking insulating film;
forming a tunneling insulating film on a side surface of the charge storage portion;
forming a semiconductor body extending in the first direction inside the hole where the blocking insulating film, the charge storage portion, and the tunneling insulating film are formed; and
replacing the plurality of first layers with a plurality of electrode layers including aluminum.

13. The method according to claim 12, wherein the blocking insulating film includes one or more oxides selected from the group consisting of silicon oxide, zirconium oxide, aluminum oxide, and hafnium oxide.

14. The method according to claim 12, wherein the siliciding includes:
forming a metal layer on a side surface of the layer including silicon;
causing silicon included in the layer including silicon and a metal included in the metal layer to react by heating; and
removing the unreacted metal layer.

15. The method according to claim 12, wherein
the siliciding includes forming a metal silicide by causing silicon included in the layer including silicon to react with a metal,
the blocking insulating film is formed using a material including an oxide of a first element, and
a free energy of oxide formation of the metal is higher than a free energy of oxide formation of the first element.

16. The method according to claim 15, wherein the first element is one or more elements selected from the group consisting of silicon, zirconium, aluminum, and hafnium.

17. The method according to claim 15, wherein the metal is one or more metals selected from the group consisting of tungsten, cobalt, and nickel.

18. The method according to claim 12, wherein the plurality of first layers are caused to recede not less than 5 nm and not more than 20 nm from the side surface of the hole.

19. The method according to claim 12, further comprising forming a slit in the stacked body,
the replacing, with the plurality of electrode layers including aluminum, of the plurality of first layers including:
removing the plurality of first layers via the slit; and
forming the electrode layers inside a space where the plurality of first layers are removed.

20. The method according to claim 19, further comprising:
forming an insulating portion on a side surface of the slit; and
forming a conductive portion inside the slit.
